(19) United States
(12) Patent Application Publication
(10) Pub. No.: US 2025/0347954 A1
(43) Pub. Date: Nov. 13, 2025

(54) DISPLAY DEVICE

(71) Applicant: HKC CORPORATION LIMITED, Shenzhen (CN)

(72) Inventors: Qiang CAO, Shenzhen (CN); Guangchen ZHANG, Shenzhen (CN); Kun LIU, Shenzhen (CN); Lidan YE, Shenzhen (CN)

(21) Appl. No.: 19/198,628

(22) Filed: May 5, 2025

(30) Foreign Application Priority Data
May 10, 2024 (CN) 202410571326.3

(51) Int. Cl. G02F 1/1335; G02F 1/13357

(52) U.S. Cl. CPC G02F 1/133601; G02F 1/133607; G02F 1/133621

(57) ABSTRACT

A display device is provided. The display device includes a display panel, a first transparent substrate, a second transparent substrate, a first dimming layer, a light source layer, a second dimming layer, a third transparent substrate, and a fourth transparent substrate that are sequentially stacked. The second transparent substrate has a greater refractive index than the first transparent substrate. The fourth transparent substrate has a less refractive index than the third transparent substrate. The first dimming layer includes multiple first dimming units. The light source layer includes multiple light sources. The second dimming layer includes multiple second dimming units. Each of the multiple first dimming units and each of the multiple second dimming units both have a first state of being a planar lens and a second state of being a concave lens.

### CROSS-REFERENCE TO RELATED APPLICATIONS

This application claims priority under 35 U.S.C. § 119(a) to Chinese Patent Application No. 202410571326.3, filed May 10, 2024, the entire disclosure of which is incorporated herein by reference.

### TECHNICAL FIELD

This disclosure relates to the field of display panel, and in particular to a display device.

### BACKGROUND

Generally, display devices can perform front display. However, with the advancement of technology and diversification of application scenarios, the display device that is only capable of performing front display cannot meet the diverse requirements of application scenarios.

### SUMMARY

In a first aspect, a display device is provided in an implementation of the present disclosure. The display device includes a display panel, a first transparent substrate, a second transparent substrate, a first dimming layer, a light source layer, a second dimming layer, a third transparent substrate, and a fourth transparent substrate that are sequentially stacked. The second transparent substrate has a greater refractive index than the first transparent substrate. The fourth transparent substrate has a less refractive index than the third transparent substrate. The first dimming layer includes multiple first dimming units. The light source layer includes multiple light sources. The second dimming layer includes multiple second dimming units. Each of the multiple first dimming units and each of the multiple second dimming units both have a first state of being a planar lens and a second state of being a concave lens. The first dimming layer, the first transparent substrate, and the second transparent substrate cooperate with one another, and the second dimming layer, the third transparent substrate, and the fourth transparent substrate cooperate with one another, to make the display device have different display states.

### BRIEF DESCRIPTION OF THE DRAWINGS

To describe the technical solutions in embodiments of the present disclosure more clearly, the accompanying drawings for use in implementations are briefly described below. Apparently, the accompanying drawings in the following description show merely some implementations of the present disclosure, and those of ordinary skill in the art may obtain other accompanying drawings from these accompanying drawings without creative effort.

FIG. 1 is a schematic structural view of a display device provided in an implementation of the present disclosure.

FIG. 2 is a schematic cross-sectional view of the display device shown in FIG. 1, taken along line I-I.

FIG. 3 is a schematic view of a first dimming unit in a first state or a second dimming unit in the first state.

FIG. 4 is a schematic view of a first dimming unit in a second state or a second dimming unit in the second state.

FIG. 5 is a schematic view of a first dimming unit in a third state or a second dimming unit in the third state.

FIG. 6 is a schematic view of a display device in a first display mode provided in an implementation of the present disclosure.

FIG. 7 is a schematic view of a display device in a second display mode provided in an implementation of the present disclosure.

FIG. 8 is a schematic view of a display device in a third display mode provided in an implementation of the present disclosure.

FIG. 9 is a schematic view of a display device in a fourth display mode provided in another implementation of the present disclosure.

FIG. 10 is a schematic view of a display device in a fifth display mode provided in another implementation of the present disclosure.

FIG. 11 is a schematic view of a second display surface of a display device performing display provided in an implementation.

FIG. 12 is a schematic view of partial optical paths of the display device shown in FIG. 2.

FIG. 13 is a schematic view of a display device provided in another implementation of the present disclosure.

FIG. 14 is a schematic view of optical paths of the display device provided in FIG. 13.

FIG. 15 is a front schematic structural view of a display device provided in an implementation of the present disclosure.

FIG. 16 is a rear schematic structural view of the display device provided FIG. 15.

FIG. 17 is a side view of the display panel shown in FIG. 15.

FIG. 18 is a schematic view of the display panel shown in FIG. 15 from another perspective.

FIG. 19 is a schematic view of optical path simulation of the display device in the second display mode shown in FIG. 7.

### DETAILED DESCRIPTION

The following will clearly and completely describe technical solutions of embodiments of the present disclosure with reference to the accompanying drawings of the embodiments of the present disclosure. Apparently, the embodiments described herein are merely some embodiments, rather than all embodiments of the present disclosure. Based on the embodiments of the present disclosure, all other embodiments obtained by those of ordinary skill in the art without creative effort shall fall within the protection scope of the present disclosure.

The terms such as “first”, “second”, etc., in the specification, the claims, and the above accompanying drawings of the present disclosure are used to distinguish different objects, rather than describing a particular order. In addition, the terms “including”, “comprising”, and “having” as well as variations thereof are intended to cover non-exclusive inclusion. For example, a process, method, system, product, or device including a series of steps or units is not limited to the listed steps or units, on the contrary, it can optionally include other steps or units that are not listed; alternatively, other steps or units inherent to the process, method, product, or device can be included either.

The term “embodiment” or “implementation” referred to herein means that particular features, structures, or properties described in conjunction with embodiments or implementations may be defined in at least one embodiment of the present disclosure. The phrase “embodiment” or “implementation” appearing in various places in the specification does not necessarily refer to the same embodiment or an independent/alternative embodiment that is mutually exclusive with other embodiments. Those skilled in the art will understand expressly and implicitly that an embodiment described in the present disclosure may be combined with other embodiments.

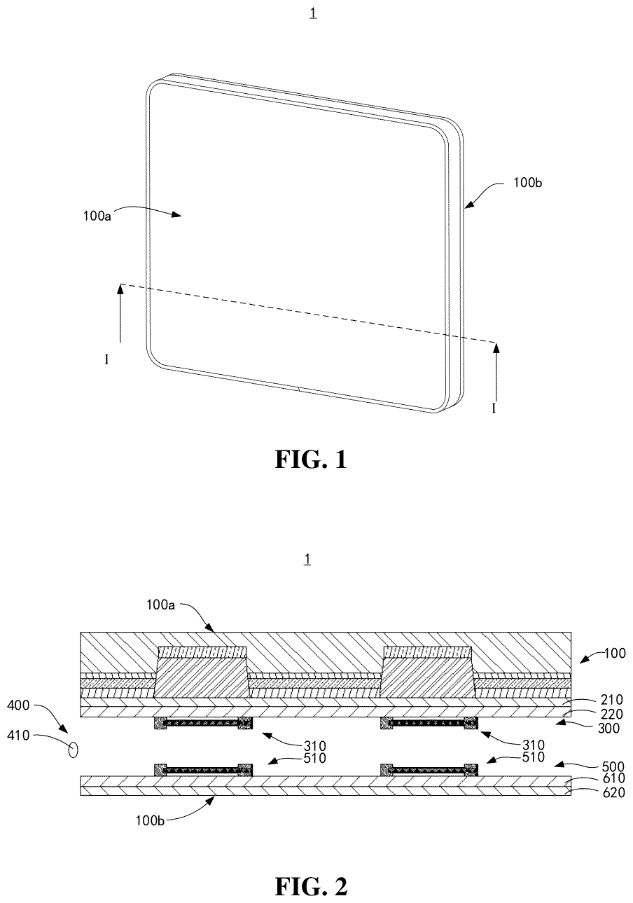

Reference can be made to FIG. 1 and FIG. 2 together, where FIG. 1 is a schematic view of a display device provided in an implementation of the present disclosure, and FIG. 2 is a schematic cross-sectional view of the display device shown in FIG. 1, taken along line I-I. The display device 1 includes a display panel 100, a first transparent substrate 210, a second transparent substrate 220, a first dimming layer 300, a light source layer 400, a second dimming layer 500, a third transparent substrate 610, and a fourth transparent substrate 620 that are sequentially stacked. The second transparent substrate 220 has a greater refractive index than the first transparent substrate 210. The fourth transparent substrate 620 has a less refractive index than the third transparent substrate 610. The first dimming layer 300 includes multiple first dimming units 310. The light source layer 400 includes multiple light sources 410. The second dimming layer 500 includes multiple second dimming units 510. Each of the multiple first dimming units 310 and each of the multiple second dimming units 510 both have a first state of being a planar lens and a second state of being a concave lens. The first dimming layer 300, the first transparent substrate 210, and the second transparent substrate 220 cooperate with one another, and the second dimming layer 500, the third transparent substrate 610, and the fourth transparent substrate 620 cooperate with one another, to make the display device 1 have different display states.

The display panel 100 may be, but is not limited to, an Organic Light-Emitting Diode (OLED) display panel.

The first transparent substrate 210 may be, but is not limited to, a glass substrate, a plastic substrate, or other transparent substrates. The second transparent substrate 220 may be, but is not limited to, a glass substrate, a plastic substrate, or other transparent substrates. The refractive index of the first transparent substrate 210 is n1. The refractive index of the second transparent substrate 220 is n2. The refractive index of the second transparent substrate 220 is greater than the refractive index of the first transparent substrate 210, that is, n2>n1. In other words, the refractive index of the first transparent substrate 210 is relatively small and the refractive index of the second transparent substrate 220 is relatively large.

The third transparent substrate 610 may be, but is not limited to, a glass substrate, a plastic substrate, or other transparent substrates. The fourth transparent substrate 620 may be, but is not limited to, a glass substrate, a plastic substrate, or other transparent substrates. The refractive index of the third transparent substrate 610 is n3. The refractive index of the fourth transparent substrate 620 is n4. The refractive index of the third transparent substrate 610 is greater than the refractive index of the fourth transparent substrate 620, that is, n3>n4. In other words, the refractive index of the fourth transparent substrate 620 is relatively small and the refractive index of the third transparent substrate 610 is relatively large. In an implementation, n3=n2, and n4=n1. In other implementations, n3#n2, and n4+n1.

In this implementation, the third transparent substrate 610 and the second transparent substrate 220 face and is spaced apart from each other, to define a receiving space. The first dimming unit 310, the light source 410, and the second dimming unit 510 are located in the receiving space. The first dimming unit 310 is disposed on a surface of the second transparent substrate 220 away from the first transparent substrate 210. The second dimming unit 510 is disposed on a surface of the third transparent substrate 610 away from the fourth transparent substrate 620. The light source 410 is located in the receiving space.

The first dimming unit 310 has the first state of being the planar lens and the second state of being the concave lens. In addition, in other implementations, the first dimming unit 310 has the first state of being the planar lens, the second state of being a concave lens, and a third state of being a convex lens. Whether the first dimming unit 310 has the third state is not limited in implementations of the present disclosure.

Accordingly, the second dimming unit 510 has the first state of being the planar lens and the second state of being the concave lens. In addition, in other implementations, the second dimming unit 510 has the first state of being the planar lens, the second state of being the concave lens, and a third state of being a convex lens. Whether the second dimming unit 510 has the third state is not limited in implementations of the present disclosure.

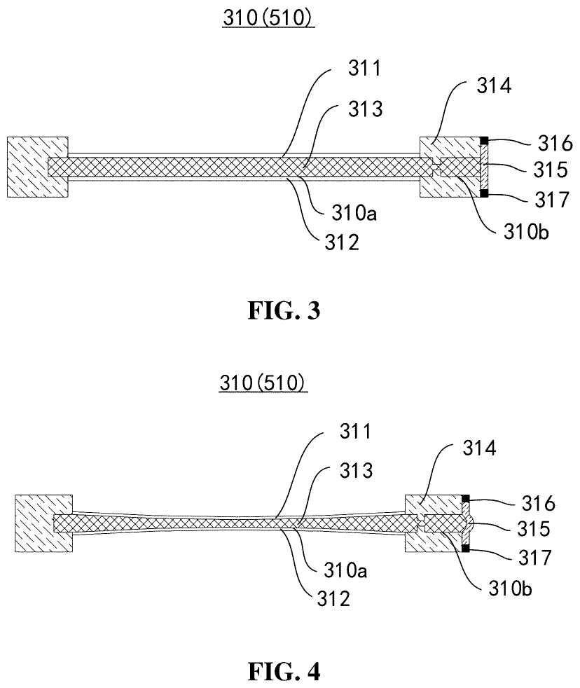

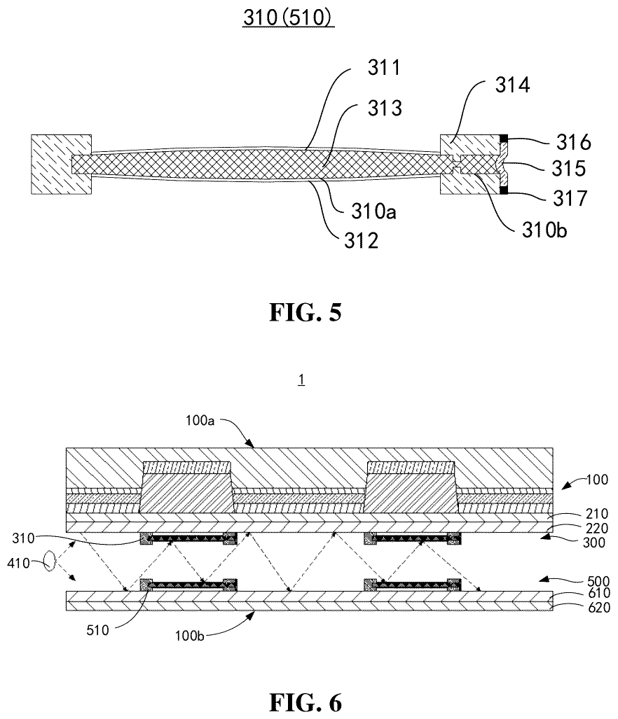

Reference can be made to FIG. 3, FIG. 4, and FIG. 5 together, where FIG. 3 is a schematic view of a first dimming unit in a first state or a second dimming unit in the first state, FIG. 4 is a schematic view of a first dimming unit in a second state or a second dimming unit in the second state, and FIG. 5 is a schematic view of a first dimming unit in a third state or a second dimming unit in the third state. The first dimming unit 310 includes a first resilient film 311, a second resilient film 312, liquid 313, a frame 314, a deformable film 315, a first electrode 316, and a second electrode 317. The first resilient film 311 and the second resilient film 312 are both fixed to the frame 314, and the first resilient film 311 and the second resilient film 312 face and are spaced apart from each other to define an accommodating space 310a. The frame 314 defines a buffer space 310b in communication with the accommodating space 310a. The liquid 313 is received in the buffer space 310b and the accommodating space 310a. The deformable film 315 is disposed on the frame 314 to seal an opening of the accommodating space 310a. The first electrode 316 and the second electrode 317 are disposed at two opposite ends of the deformable film 315, respectively. The first electrode 316 and the second electrode 317 can receive a control voltage, and control the state of the deformable film 315 under the action of the control voltage. Under the action of the control voltage, the deformable film 315 has a normal state, an expanded state in which the deformable film 315 protrudes in a direction away from the deformable film 315, and a retracted state in which the deformable film 315 protrudes towards the receiving space.

The material of the deformable film 315 may be, but is not limited to, an electro-deformation material or an electrostrictive material.

When the shape-sensitive film 315 is in a normal state, the first dimming unit 310 is in the first state of being the planar lens. When the deformable film 315 is in an expanded state, the first dimming unit 310 is in the second state of being the concave lens. Specifically, when the deformable film 315 is switched from the normal state to the outwardly expanded state, part of the liquid 313 in the accommodating space 310a flows into the buffer space 310b. The first dimming unit 310 in the second state of being the concave lens diverges light incident onto the first dimming unit 310. When the deformable film 315 is in a retracted state, the first dimming unit 310 is in a third state of being a convex lens. Specifically, when the deformable film 315 is switched from the normal state to the retracted state, part of the liquid 313 in the buffer space 310b flows into the accommodating space 310a. The first dimming unit 310 in a third state of being a convex lens converges light incident onto the first dimming unit 310.

It can be understood that, when the first dimming unit 310 is in the second state, the curvature of the first dimming unit 310 in a shape of a concave lens can be adjusted through the control signal. Accordingly, when the first dimming unit 310 is in a third state, the curvature of the first dimming unit 310 in a shape of a convex lens can be adjusted through the control signal.

Accordingly, when the second dimming unit 510 is in a second state, the curvature of the second dimming unit 510 in a shape of a concave lens can be adjusted through the control signal. Accordingly, when the second dimming unit 510 is in a third state, the curvature of the second dimming unit 510 in a shape of a convex lens can be adjusted through the control signal.

It can be understood that, in this implementation, the second dimming unit 510 and the first dimming unit 310 have the same structure. The second dimming unit 510 also includes a first resilient film 311, a second resilient film 312, liquid 313, a frame 314, a deformable film 315, a first electrode 316, and a second electrode 317. For the structure of each component in the second dimming unit 510, please refer to the structure of each component in the first dimming unit 310, which will not be repeated herein. It can be understood that, in other implementations, the second dimming unit 510 and the first dimming unit 310 may have different structures, as long as the second dimming unit 510 has the first state of being the planar lens and the second state of being the concave lens. As can be seen from the above description of the first dimming unit 310, the first dimming unit 310 is an adjustable liquid lens (also referred to as a liquid dimming lens). Accordingly, the second dimming unit 510 is a liquid lens.

When light is transmitted from an optically denser medium to an optically thinner medium and an incident angle is larger than or equal to a critical angle C, the light is totally reflected and will not exit from the optically thinner medium. The critical angle C satisfies: SinC=1/n, where n is a refractive index. The refractive index of the second transparent substrate 220 is greater than the refractive index of the first transparent substrate 210. Light emitted by the light source 410 is incident to the first transparent substrate 210 from the second transparent substrate 220, which is equivalent to the light travelling from an optically denser medium to an optically thinner medium. When an emission angle of the light emitted by the light source 410 is larger than or equal to the critical angle, the light emitted by the light source 410 will be totally reflected on a surface of the first transparent substrate 210 attached to the second transparent substrate 220, and will not exit from the first transparent substrate 210.

Accordingly, light emitted by the light source 410 is incident to the fourth transparent substrate 620 from the third transparent substrate 610, which is equivalent to the light travelling from an optically denser medium to an optically thinner medium. When an emission angle of the light emitted by the light source 410 is larger than or equal to the critical angle, the light emitted by the light source 410 will be totally reflected on a surface of the fourth transparent substrate 620 attached to the third transparent substrate 610, and will not exit from the fourth transparent substrate 620.

Accordingly, when the incident light is smaller than the critical angle C, the light will not be totally reflected, and the light can exit through the second transparent substrate 220 and the first transparent substrate 210. Accordingly, when the incident light is smaller than the critical angle C, the light will not be totally reflected, and the light can exit through the third transparent substrate 610 and the fourth transparent substrate 620.

The first dimming unit 310 has the first state of being the planar lens and the second state of being the concave lens. An angle at which light exiting from the first dimming unit 310 in the first state is incident onto the second transparent substrate 220 is different from an angle at which light exiting from the first dimming unit 310 in the second state is incident onto the second transparent substrate 220.

Specifically, on condition that the first dimming unit 310 is in the first state of being the planar lens, when light emitted by the light source 410 is incident to the first dimming unit 310, the light travels from air to the liquid 313, which is equivalent to the light travelling from an optically thinner medium to an optically denser medium. Therefore, total reflection will not occur on the first dimming unit 310.

However, when the first dimming unit 310 is in the first state of being the planar lens, light emitted from the first dimming unit 310 to the second transparent substrate 220 and the first transparent substrate 210 will be totally reflected, and the light cannot exit through the first transparent substrate 210.

Compared with the first dimming unit 310 being in the first state of being the planar lens, when the first dimming unit 310 is in the second state of being the concave lens, the angle of the light emitted from the first dimming unit 310 changes. In this state, the incident angle of the light incident to the second transparent substrate 220 and the first transparent substrate 210 also changes, so that the condition for total reflection is no longer met. Therefore, the light can exit through the first transparent substrate 210.

Accordingly, the second dimming unit 510 has the first state of being the planar lens and the second state of being the concave lens. An angle at which light exiting from the second dimming unit 510 in the first state is incident onto the third transparent substrate 610 is different from an angle at which light exiting from the second dimming unit 510 in the second state is incident onto the third transparent substrate 610.

Specifically, on condition that the second dimming unit 510 is in the first state of being the planar lens, when light emitted by the light source 410 is incident to the second dimming unit 510, the light travels from air to the liquid 313, which is equivalent to the light travelling from an optically thinner medium to an optically denser medium. Therefore, total reflection will not occur on the second dimming unit 510.

However, when the second dimming unit 510 is in the first state of being the planar lens, light emitted from the second dimming unit 510 to the third transparent substrate 610 and the fourth transparent substrate 620 will be totally reflected, and the light cannot exit through the fourth transparent substrate 620.

Compared with the second dimming unit 510 being in the first state of being a planar lens, when the second dimming unit 510 is in the second state of being the concave lens, the angle of the light emitted from the second dimming unit 510 changes. In this state, the incident angle of the light incident to the third transparent substrate 610 and the fourth transparent substrate 620 also changes, so that the condition for total reflection is no longer met. Therefore, the light can exit through the fourth transparent substrate 620.

For convenience of description, it is defined that the display panel 100 has a first display surface 100a away from the first transparent substrate 210, and the fourth transparent substrate 620 has a second display surface 100b away from the third transparent substrate 610. In an implementation, the first display surface 100a is also referred to as a front surface, and the second display surface 100b is also referred to as a rear surface. It can be understood that, as the placement posture of the display panel 100 changes, the first display surface 100a may also be referred to as a rear surface, and the second display surface 100b may also be referred to as a front surface.

In summary, the first dimming unit 310 in the first state of being the planar lens and the first dimming unit 310 in the second state of being the concave lens have different effects on light, so that angles at which light incident onto the second transparent substrate 220 are different. Therefore, light cannot exit from the first transparent substrate 210 when the first dimming unit 310 is in the first state of being the planar lens, and light can exit from the first transparent substrate 210 when the first dimming unit 310 is in the second state of being the concave lens. Accordingly, the second dimming unit 510 in the first state of being the planar lens and the second dimming unit 510 in the second state of being the concave lens have different effects on light, so that angles at which light incident on the third transparent substrate 610 are different. Therefore, light cannot exit from the fourth transparent substrate 620 when the second dimming unit 510 is in the first state of being the planar lens, and light can exit from the fourth transparent substrate 620 when the second dimming unit 510 is in the second state of being the concave lens. In addition, in combination with the state in which the display panel 100 displays or the state in which the display panel 100 does not display, the display device 1 can have various display modes, so that the display requirements of the display device 1 in various scenarios can be met.

The various display modes of the display device 1 will be described in detail later.

For convenience of description, it is defined that the display device 1 has a first display surface 100a and a second display surface 100b opposite to the first display surface 100a. Specifically, the display panel 100 has the first display surface 100a away from the first transparent substrate 210, and the fourth transparent substrate 620 has the second display surface 100b away from the third transparent substrate 610.

Reference can be made to FIG. 6, which is a schematic view of a display device in a first display mode provided in an implementation of the present disclosure. When the first dimming unit 310 is in the first state and the second dimming unit 510 is in the first state, the display device 1 is in a first display mode. The first display mode is a state in which the first display surface 100a of the display device 1 performs shared display and the second display surface 100b does not display.

When the first dimming unit 310 is in the first state of being the planar lens, light emitted from the first dimming unit 310 to the second transparent substrate 220 and the first transparent substrate 210 are totally reflected, and the light cannot exit through the first transparent substrate 210.

When the second dimming unit 510 is in the first state of being the planar lens, light emitted from the second dimming unit 510 to the third transparent substrate 610 and the fourth transparent substrate 620 are totally reflected, and the light cannot exit from the fourth transparent substrate 620.

When the display panel 100 displays, a content displayed by the display panel 100 exits through the first display surface 100a. Since the first dimming unit 310 is in the first state of being the planar lens, light emitted from the first dimming unit 310 to the second transparent substrate 220 and the first transparent substrate 210 will be totally reflected, the light cannot exit through the first transparent substrate 210. Therefore, the light emitted by the light source 410 cannot exit through the first display surface 100a, and thus cannot interfere with the content displayed on the first display surface 100a by the display panel 100. In this way, a user can view the content displayed on the first display surface 100a from various angles relative to the first display surface 100a. The first display mode includes a mode in which the first display surface 100a of the display device 1 performs shared display.

In addition, when the second dimming unit 510 is in the first state, light emitted from the second dimming unit 510 to the third transparent substrate 610 and the fourth transparent substrate 620 are totally reflected, and the light cannot exit through the fourth transparent substrate 620. Therefore, the light emitted by the light source 410 cannot exit through the second display surface 100b, and the display device 1 cannot perform rear display.

In summary, the first display mode is a state in which the first display surface 100a of the display device 1 performs shared display and the second display surface 100b does not display.

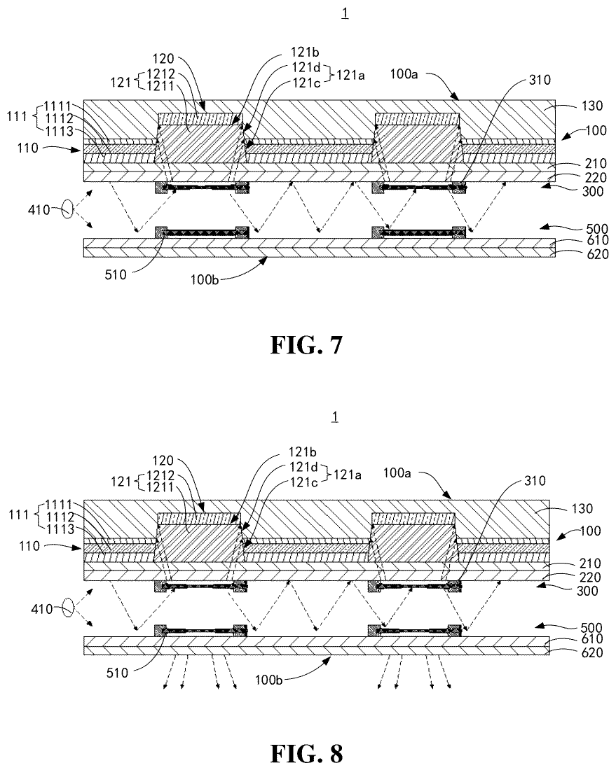

Reference can be made FIG. 7, which is a schematic view of a display device in a second display mode provided in an implementation of the present disclosure. When the first dimming unit 310 is in the second state and the second dimming unit 510 is in the first state, the display device 1 is in a second display mode. The second display mode is a state in which the first display surface 100a of the display device 1 performs privacy display and the second display surface 100b of the display device 1 does not display.

When the first dimming unit 310 is in the second state, light emitted by the light source 410 can exit through the first transparent substrate 210, which may interfere with a part of an image displayed on the first display surface 100a out of a certain angle range, while a part of the image displayed on the first display surface 100a within a certain angle range can be viewed normally, so that the first display surface 100a is in a privacy display mode.

In addition, when the second dimming unit 510 is in the first state, light emitted from the second dimming unit 510 to the third transparent substrate 610 and the fourth transparent substrate 620 are totally reflected, and the light cannot exit through the fourth transparent substrate 620. Therefore, the light emitted by the light source 410 cannot exit through the second display surface 100b, and the display device 1 cannot perform rear display.

In summary, the second display mode is a state in which the first display surface 100a of the display device 1 performs privacy display and the second display surface 100b does not display.

Reference can be made to FIG. 8, which is a schematic view of a display device in a third display mode provided in an implementation of the present disclosure. When the first dimming unit 310 is in the second state and the second dimming unit 510 is in the second state, the display device 1 is in a third display mode. The third display mode is a state in which the first display surface 100a of the display device 1 performs privacy display and the second display surface 100b displays.

When the display panel 100 displays, the content displayed by the display panel 100 is emitted through the first display surface 100a. When the first dimming unit 310 is in the second state, the light emitted by the light source 410 can exit from the first transparent substrate 210, which may interfere with a part of an image displayed on the first display surface 100a out of a certain angle range, which a part of the image displayed on the first display surface 100a within a certain angle range can be viewed normally, so that the first display surface 100a is in a privacy display mode.

Accordingly, when the second dimming unit 510 is in the second state, the light emitted by the light source 410 can exit through the fourth transparent substrate 620, so that the display device 1 can display on the second display surface 100b.

In summary, the third display mode is a state in which the first display surface 100a of the display device 1 performs privacy display and the second display surface 100b displays.

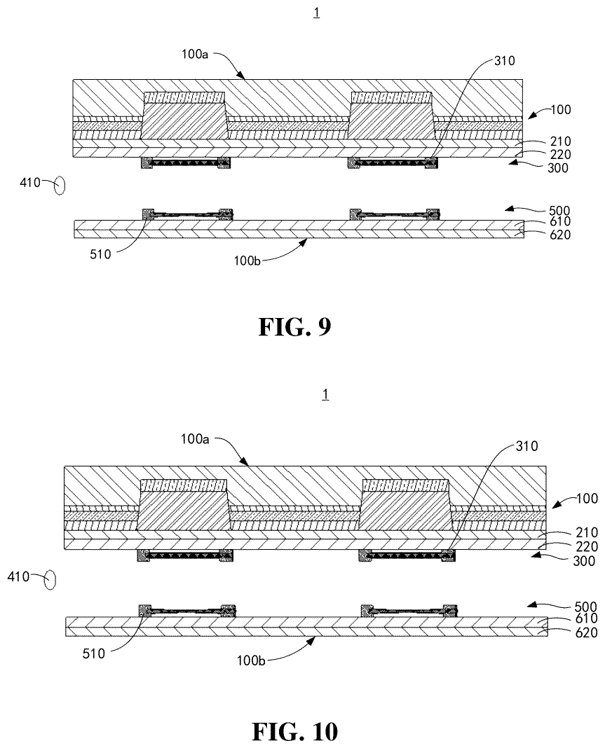

Reference can be made to FIG. 9, which is a schematic view of a display device in a fourth display mode provided in an implementation of the present disclosure. The display device 1 further has a fourth display mode. The fourth display mode is a state in which the first display surface 100a of the display device 1 does not display and the second display surface 100b displays. When the display device 1 is in the fourth display mode, the first dimming unit 310 is in the first state, and the second dimming unit 510 is in the second state.

When the display device 1 is in the fourth display mode, the first dimming unit 310 is in the first state. Since the first dimming unit 310 is in the first state of being the planar lens, light emitted from the first dimming unit 310 to the second transparent substrate 220 and the first transparent substrate 210 are totally reflected, and the light cannot exit through the first transparent substrate 210, so that the first display surface 100a of the display panel 100 has no content displayed by the display panel 100, and no light emitted by the light source 410 exits through the first display surface 100a.

Accordingly, when the second dimming unit 510 is in the second state, light emitted by the light source 410 can exit through the fourth transparent substrate 620, so that the display device 1 can display on the second display surface 100b.

In summary, the fourth display mode is a state in which the first display surface 100a of the display device 1 does not display and the second display surface 100b of the display device 1 displays.

Reference can be made to FIG. 10, which is a schematic view of a display device in a fifth display mode provided in an implementation of the present disclosure. When the first dimming unit 310 is in the first state and the second dimming unit 510 is in the second state, the display device 1 is in a fifth display mode. The fifth display mode is a state in which the first display surface 100a of the display device 1 performs shared display and the second display surface 100b displays.

When the first dimming unit 310 is in the first state of being the planar lens, light emitted from the first dimming unit 310 to the second transparent substrate 220 and the first transparent substrate 210 are totally reflected, and the light cannot exit through the first transparent substrate 210.

When the display panel 100 displays, the content displayed by the display panel 100 exits through the first display surface 100a. Since the first dimming unit 310 is in the first state of being the planar lens, the light emitted from the first dimming unit 310 to the second transparent substrate 220 and the first transparent substrate 210 are totally reflected, and the light cannot exit through the first transparent substrate 210. Therefore, the light emitted by the light source 410 cannot exit through the first display surface 100a, and thus cannot interfere with the content displayed on the first display surface 100a by the display panel 100. In this way, the user can view the content displayed on the first display surface 100a from various angles relative to the first display surface 100a. The fifth display mode includes a mode in which the first display surface 100a of the display device 1 performs shared display.

Accordingly, when the second dimming unit 510 is in the second state, light emitted by the light source 410 may exit through the fourth transparent substrate 620, so that the display device 1 can display on the second display surface 100b.

In summary, the fifth display mode is a state in which the first display surface 100a of the display device 1 performs the shared display and the second display surface 100b thereof performs the display.

Referring to FIG. 7 and FIG. 8, the display panel 100 includes a light-emitting layer 110 and a pixel definition layer 120. The light-emitting layer 110 includes multiple light-emitting units 111 arranged at intervals. The pixel definition layer 120 includes multiple pixel definition portions 121 arranged at intervals. Each pixel definition portion 121 includes a pixel definition sub-portion 1211 and a light-shielding sub-portion 1212. The pixel definition sub-portion 1211 has a bearing surface 121b that is away from the first transparent substrate 210 and a peripheral side surface 121a that is connected to the bearing surface 121b in a bent manner. The peripheral side surface 121a includes a first peripheral side sub-surface 121c and a second peripheral side sub-surface 121d. A side surface of a light-emitting unit 111 abuts against the first peripheral side sub-surface 121c and avoids the second peripheral side sub-surface 121d. The second peripheral side sub-surface 121d is closer to the bearing surface 121b than the first peripheral side sub-surface 121c. The bearing surface 121b is used to bear the light-shielding sub-portion 1212. When the first display surface 100a of the display device 1 performs privacy display, light emitted by the light source 410 passes through the second peripheral side sub-surface 121d and exits through the first display surface 100a.

It may be noted that, when the first display surface 100a of the display device 1 performs privacy display, the display mode of the second display surface 100b of the display device 1 is not limited, that is, the second display surface 100b of the display device 1 may display or not display.

In this implementation, both the light incident to the light-shielding sub-portion 1212 and the light incident to the first peripheral sub-surface 121c cannot exit from the first display surface 100a. The light incident to the second peripheral side sub-surface 121d can exit through the first display surface 100a.

When the light exiting from the second peripheral side sub-surface 121d exits from the first display surface 100a, the light may interfere with a part of the image displayed on the first display surface 100a out of a certain angle range, while a part of the image displayed on the first display surface 100a within a certain angle range can be viewed normally, so that the first display surface 100a is in a privacy display mode.

For the display device 1 provided in implementations of the present disclosure, by designing the structure of the pixel definition layer 120 and the structure of the light-emitting layer 110, the first display surface 100a of the display device 1 can realize the privacy display mode, which is simple and feasible without additionally providing other components.

In this implementation, the display panel 100 further includes an encapsulation layer 130. The encapsulation layer 130 is configured to encapsulate the light-emitting layer 110 and the pixel definition layer 120. It can be understood that, in other implementations, the display panel 100 may not include the encapsulation layer 130.

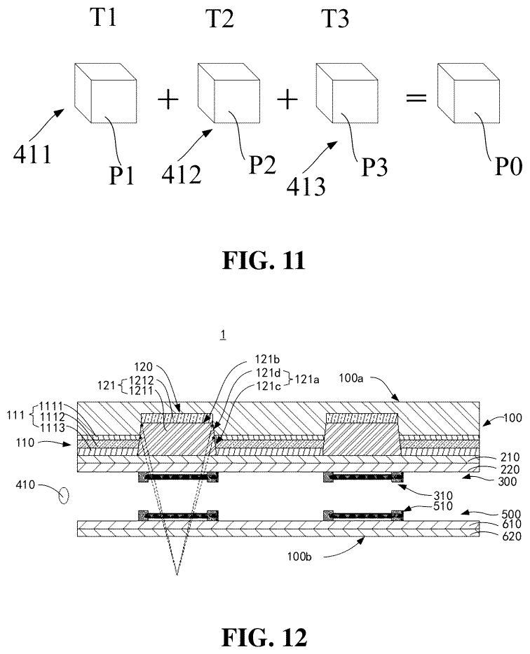

Referring further to FIG. 8, FIG. 9, and FIG. 10, and further to FIG. 11, FIG. 11 is a schematic view of a second display surface of a display device performing display provided in an implementation. The principle of displaying on the second display surface 100b is described below. It may be noted that, when the second display surface 100b of the display device 1 displays, the mode of first display surface 100a of the display device 1 is not limited. The multiple light sources 410 include a first light source 411, a second light source 412, and a third light source 413. The first light source 411, the second light source 412, and the third light source 413 are different from one another in color. When the second display surface 100b displays, one frame time for image display on the second display surface 100b of the display device 1 includes a first sub-frame time T1, a second sub-frame time T2, and a third sub-frame time T3. The first light source 411 is configured for display in the first sub-frame time T1. The second light source 412 is configured for display in the second sub-frame time T2. The third light source 413 is configured for display in the third sub-frame time T3.

In this implementation, the first light source 411 is a red light source, the second light source 412 is a green light source, and the third light source 413 is a blue light source. It can be understood that, in other implementations, the first light source 411, the second light source 412, and the third light source 413 may be other combinations of red light source, green light source, and blue light source, which are not limited herein.

One frame time for image display on the second display surface 100b of the display device 1 includes the first sub-frame time T1, the second sub-frame time T2, and the third sub-frame time T3. The first sub-frame time T1, the second sub-frame time T2, and the third sub-frame time T3 are sequentially continuous. In the first sub-frame time T1, the first light source 411 is configured for display, to obtain a first sub-frame image P1. In the second sub-frame time T2, the second light source 412 is configured for display, to obtain a second sub-frame image P2. In the third sub-frame time T3, the third light source 413 is configured for display, to obtain a third sub-frame image P3. The first sub-frame image P1, the second sub-frame image P2, and the third sub-frame image P3 are overlaid as one frame image P0. It can be seen therefrom that the second display surface 100b of the display device 1 can normally display an image.

In addition, by adjusting the concavo-convex degree of the second dimming unit 510 through the control signal, the amount of light exiting through the second dimming unit 510 to the second display surface 100b, so that the grayscale of the image displayed on the second display surface 100b can be changed. In this implementation, when the second dimming unit 510 is in the second state, the curvature of the second dimming unit 510 in a shape of a concave lens can be adjusted through the control signal.

In summary, the display device 1 provided in implementations of the present disclosure has one or more display modes, for example, the display device 1 may have one or more of a first display mode, a second display mode, a third display mode, a fourth display mode, or a fifth display mode, and can be applicable to more usage scenarios. For example, the display device 1 provided in implementations of the present disclosure is applicable to a display scenario of a bank counter. The first display surface 100a of the display device 1 may face a customer for display, and the second display surface 100b of the display device 1 may face bank staff for display, so that the bank staff can guide the customer to perform operations and the like. In addition, when the display device 1 is in the third display mode, that is, when the first display surface 100a of the display device 1 performs privacy display and the second display surface 100b of the display device 1 displays, the first display surface 100a of the display device 1 cannot only display for the customer, but also play a role in preventing people around the customer from peeking at the content displayed on the first display surface 100a.

Referring to FIG. 7 and FIG. 8, the multiple first dimming units 310 are aligned with the multiple pixel definition portions 121 in a one-to-one correspondence, and the multiple first dimming units 310 are aligned with the multiple second dimming units 510 in a one-to-one correspondence.

That the first dimming unit 310 is aligned with the display pixel definition portion 121 may be the following. An orthographic projection of the first dimming unit 310 on the first transparent substrate 210 overlaps an orthographic projection of the pixel definition portion 121 on the first transparent substrate 210.

That the first dimming unit 310 is aligned with the second dimming unit 510 may be the following. The orthographic projection of the first dimming unit 310 on the first transparent substrate 210 overlaps an orthographic projection of the second dimming unit 510 on the first transparent substrate 210.

In this implementation, the first dimming unit 310 is aligned with the pixel definition portion 121, and the first dimming unit 310 is aligned with the second dimming unit 510, so that the display device 1 is easy to assemble.

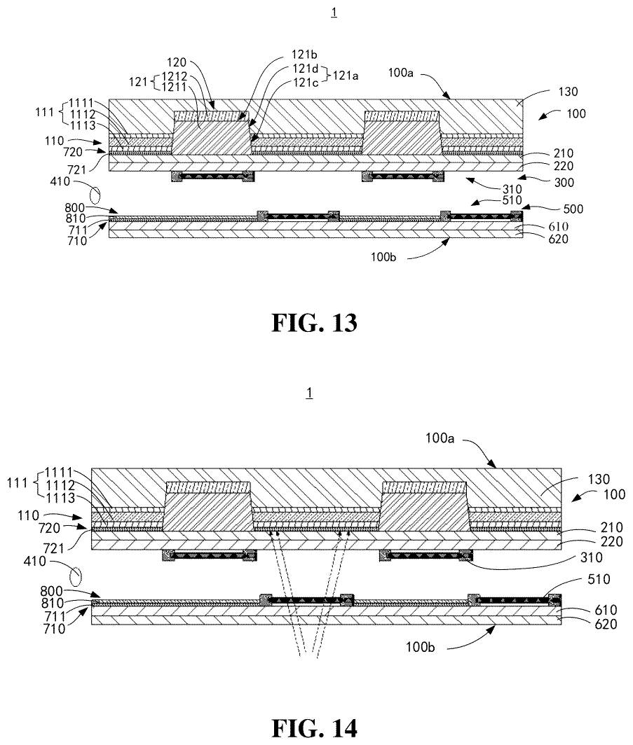

Reference can be made to FIG. 12, FIG. 13, and FIG. 14 together, where FIG. 12 is a schematic view of partial optical paths of the display device shown in FIG. 2, FIG. 13 is a schematic view of a display device provided in another implementation of the present disclosure, and FIG. 14 is a schematic view of optical paths of the display device provided in FIG. 13. In this implementation, the multiple first dimming units 310 are aligned with the multiple pixel definition portions 121 in a one-to-one correspondence, and the multiple second dimming units 510 are aligned with the multiple light-emitting units 111 in a one-to-one correspondence. The display device 1 further includes a first light-shielding layer 710 and a light-reflecting layer 800. The first light-shielding layer 710 includes multiple first light-shielding portions 711 arranged at intervals. The light-reflecting layer 800 includes multiple light-reflecting portions 810 arranged at intervals. The multiple first light-shielding portion 711 are disposed on a surface of the third transparent substrate 610 facing the second transparent substrate 220. Each the light-reflecting portion 810 is disposed on a surface of a corresponding first light-shielding portion 711 facing the second transparent substrate 220. The multiple first light-shielding portions 711 and the multiple second dimming units 510 are alternately arranged at intervals. Each of the multiple light-reflecting portions 810 avoids each of the multiple second dimming units 510. In FIG. 12, the first dimming unit 310 of the display device 1 is aligned with the second dimming unit 510, so that light (such as natural light) incident onto the display device 1 from the second display surface 100b at a small angle can enter the display device 1 and exit from the first the first display surface 100a. Therefore, on condition that the first display surface 100a of the display device 1 is in a shared display state, when the content displayed on the first display surface 100a is viewed from a specific angle, the light (such as natural light) is viewed, and thus the display effect of the first display surface 100a is affected.

In an implementation, the first light-shielding layer 710 may be, but is not limited to, made of a light-shielding ink, or a material for preparing a black matrix. The material of the first light-shielding layer 710 is not limited in this implementation. In an implementation, the material of the light-reflecting layer 800 may be, but is not limited to, a silver film, a silver mirror, or other material capable of reflecting light.

Referring to FIG. 13 and FIG. 14, in the display device 1 of FIG. 13, when light (such as natural light) incident onto the display device 1 from the second display surface 100b at a small angle enters the display device 1, the light will be absorbed by the first light-shielding layer 710. Therefore, the light will not exit through the first display surface 100a of the display device 1, thereby reducing or even avoiding the influence of the light incident from the second display surface 100b on the content displayed on the first display surface 100a. When the light incident from the second display surface 100b is natural light, the display device 1 in an implementation provided in FIG. 13 can reduce or even avoid interference of the natural light. In addition, the first light-shielding layer 710 can reduce reflection of light, and improve the contrast of the display panel 100 when the display panel 100 displays on the first display surface 100a. Accordingly, the light-shielding layer can also reduce reflection of light, and improve the contrast of the display panel 100 when the display panel 100 displays on the second display surface 100b.

In addition, the light-reflecting layer 800 can reflect the light emitted by the light source 410 to the first dimming unit 310 or the second dimming unit 510, to reduce or even avoid absorption of the light emitted by the light source 410 by the first light-shielding layer 710, so that the intensity of light emitted from the second display surface 100b of the display panel 100 is relatively strong, and the display effect is good. Moreover, since the absorption of the light emitted by the light source 410 by the first light-shielding layer 710 can be reduced or even avoided, the intensity of the light emitted from the first display surface 100a of the display panel 100 is relatively strong, so that the display device 1 has a better privacy effect when the first display surface 100a performs privacy display on the first display surface 100a.

Referring further to FIG. 13, when the display device 1 further includes the first light-shielding layer 710 and the light-reflecting layer 800, the display device 1 further includes a second light-shielding layer 720. The second light-shielding layer 720 includes multiple second light-shielding portions 721 arranged at intervals. The light-emitting unit 111 includes a cathode sub-layer 1111, a light-emitting sub-layer 1112, and an anode sub-layer 1113 sequentially stacked. The anode sub-layer 1113 is closer to the first transparent substrate 210 than the cathode sub-layer 1111. Each second light-shielding portions 721 is disposed at one side of a corresponding anode sub-layer 1113 close to the first transparent substrate 210. Each of the multiple second light-shielding portions 721 avoids each of the multiple pixel definition portions 121.

For the display device 1 provided in implementations of the present disclosure, when light (such as natural light) incident onto the display device 1 from the second display surface 100b at a small angle enters the display device 1, the light will be absorbed by the second light-shielding layer 720. Therefore, the light will not exit through the first display surface 100a of the display device 1, thereby reducing or even avoiding the influence of the light incident from the second display surface 100b on the content displayed on the first display surface 100a. When the light incident from the second display surface 100b is natural light, the display device 1 in an implementation provided in FIG. 13 can reduce or even avoid interference of the natural light. In addition, the second light-shielding layer 720 can also reduce reflection of light, and improve the contrast of the display panel 100 when the display panel 10 displays on the first display surface 100a. Accordingly, the light-shielding layer can also reduce reflection of light, and improve the contrast of the display panel 100 when the display panel 100 displays on the second display surface 100b.

It can be understood that, in this implementation, for example, when the display device 1 includes the first light-shielding layer 710 and the light-reflecting layer 800, the display device 1 further includes the second light-shielding layer 720. It can be understood that, in other implementations, when the display device 1 includes the first light-shielding layer 710 and the light-reflecting layer 800, the display device 1 may not include the second light-shielding layer 720.

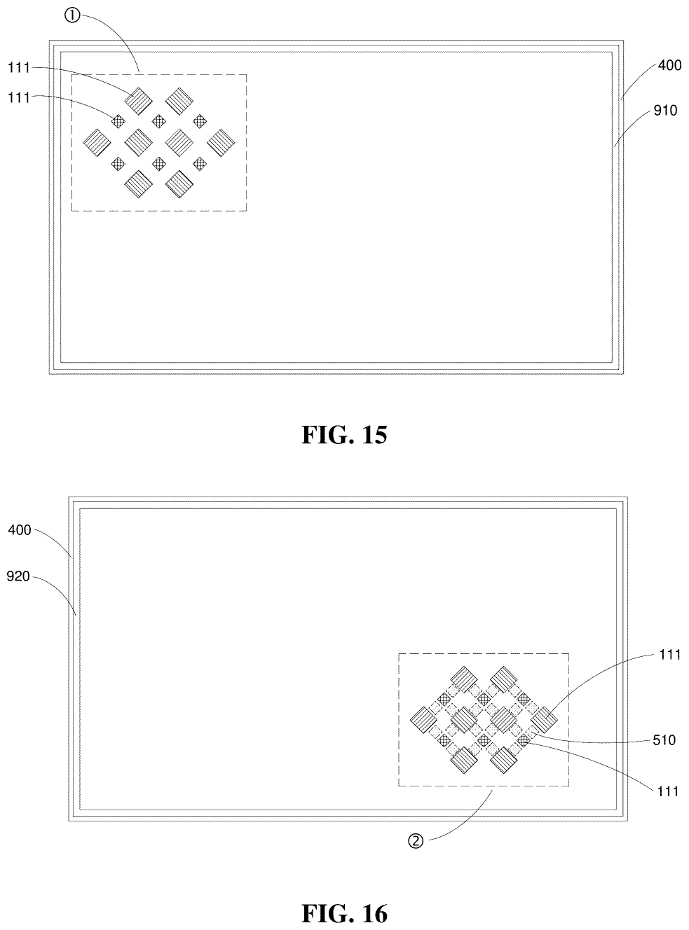

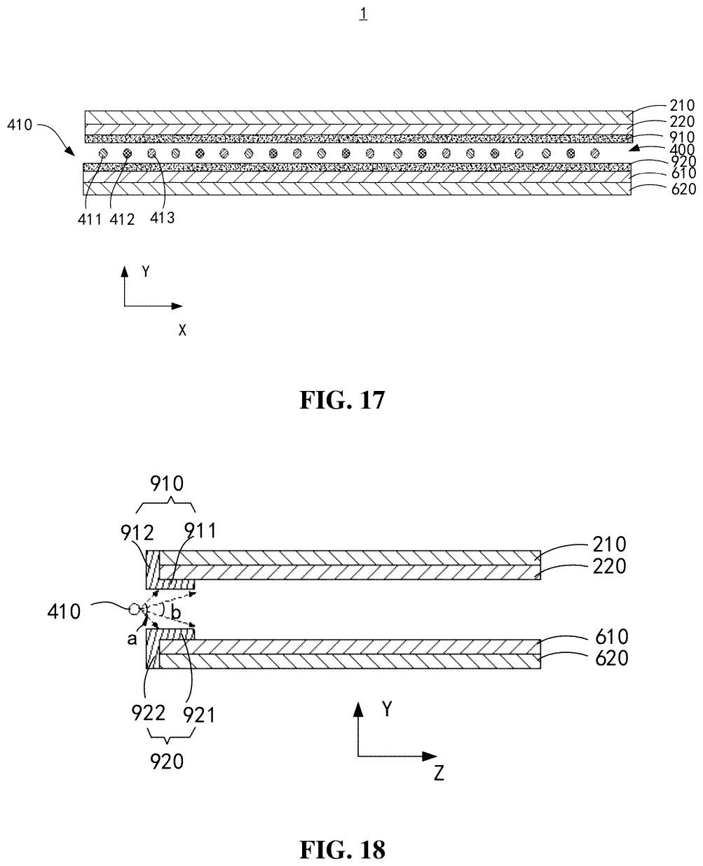

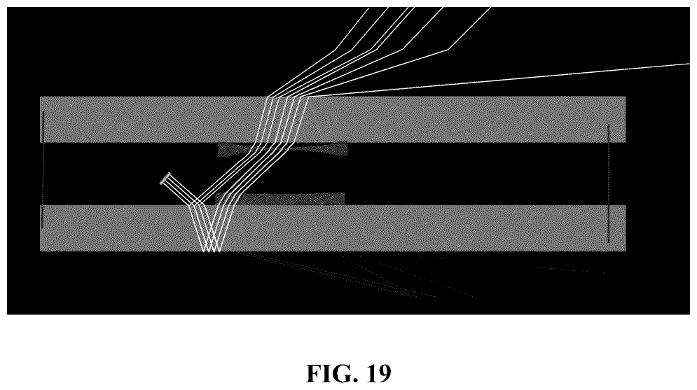

Reference can be made to FIG. 15, FIG. 16, FIG. 17, and FIG. 18, where FIG. 15 is a front schematic structural view of a display device provided in an implementation of the present disclosure, FIG. 16 is a rear schematic structural view of the display device provided in FIG. 15, FIG. 17 is a side view of the display panel shown in FIG. 15, and FIG. 18 is a schematic view of the display panel shown in FIG. 15 from another perspective. In this implementation, only light-emitting units 111 in some regions of the display device 1 are illustrated. Region \textcircled{1} in FIG. 15 illustrates a schematic arrangement of the multiple light-emitting units 111. Region \textcircled{2} in FIG. 16 illustrates multiple light-emitting units 111 and multiple second dimming units 510. It can be understood that there may also be multiple second dimming units 510 in region \textcircled{1}, which are not illustrated. It can be seen from this implementation that, the second dimming units 510 are arranged corresponding to gaps between adjacent light-emitting units 111. The second dimming unit 510 is equivalent to a pixel when the display device 1 displays on the second display surface 100b.

It can be understood that, in the schematic view of the implementation of the present disclosure, the arrangement of the multiple light-emitting units 111 in region \textcircled{1} and region \textcircled{2} is merely a schematic view of the arrangement of the light-emitting units 111, and may not be construed as a limitation to the display device 1 provided in the implementation of the present disclosure.

In this implementation, the display device 1 further includes a first light-absorbing layer 910 and a second light-absorbing layer 920. The first light-absorbing layer 910 is disposed at the first transparent substrate 210 and the second transparent substrate 220. The second light-absorbing layer 920 is disposed at the third transparent substrate 610 and the fourth transparent substrate 620.

Referring to FIG. 17, the first light-absorbing layer 910 includes a first light-absorbing portion 911 and a second light-absorbing portion 912 that are connected in a bent manner. The first light-absorbing portion 911 is disposed on a surface of the second transparent substrate 220 away from the first transparent substrate 210, and the first light-absorbing portion 911 is disposed at an edge of the second transparent substrate 220. The second light-absorbing portion 912 is disposed on a side surface of the first transparent substrate 210 and a side surface of the second transparent substrate 220.

The second light-absorbing layer 920 includes a third light-absorbing portion 921 and a fourth light-absorbing portion 922 that connected in a bent manner. The third light-absorbing portion 921 is disposed on a surface of the third transparent substrate 610 away from the fourth transparent substrate 620, and the third light-absorbing portion 921 is disposed at an edge of the third transparent substrate 610. The fourth light-absorbing portion 922 is disposed on a side surface of the third transparent substrate 610 and a side surface of the fourth transparent substrate 620.

An angle of light emitted by the light source 410 is a first angle a. The first light-absorbing portion 911 of the first light-absorbing layer 910 and the third light-absorbing portion 921 of the second light-absorbing layer 920 are disposed corresponding to the light source 410, so that an angle at which light emitted by the light source 410 exit through the first light-absorbing portion 911 of the first light-absorbing layer 910 and the third light-absorbing portion 921 of the second light-absorbing layer 920 is a second angle b. The second angle b is smaller than the first angle a.

The angle of the light emitted by the light source 410 relative to the first transparent substrate 210 is larger than a reflection angle at which total reflection occurs on the first transparent substrate 210. The angle of the light emitted by the light source 410 relative to the fourth transparent substrate 620 is larger than a reflection angle at which total reflection occurs on the fourth transparent substrate 620.

The second light-absorbing portion 912 is configured to absorb light incident onto the side surface of the first transparent substrate 210 and the side surface of the second transparent substrate 220. Accordingly, the fourth light-absorbing portion 922 is configured to absorb light incident onto the side surface of the third transparent substrate 610 and the side surface of the fourth transparent substrate 620. In this way, exitance of light from the side surface of the display device 1 can be reduced or even avoided, to improve the display effect of the display device 1.

Reference can be made to FIG. 19, which is a schematic view of optical path simulation of the display device in the second display mode shown in FIG. 7. When the first dimming unit 310 is in the second state and the second dimming unit 510 is in the first state, the display device 1 is in the second display mode. The second display mode is a state in which the first display surface 100a of the display device 1 performs privacy display and the second display surface 100b of the display device 1 does not display.

In summary, the display device 1 provided in an implementation of the present disclosure has various display modes, and can be applicable to different scenarios.

In addition, in an implementation, the display device 1 can perform front display (that is, the first display surface 100a displays) and rear display (that is, the second display surface 100b displays), thereby realizing double-sided display. Moreover, the display device 1 can have two modes of privacy display and shared display when performing front display, and the two modes can be switched.

In an implementation, the display panel 100 of the display device 1 is an OLED panel. Therefore, the display device 1 may be regarded as addition of rear display on the basis of the OLED panel as the front display panel, that is, the display device 1 can realize double-sided display.

At one side of the display panel 100, when the light emitted by the light source 410 exits from the first display surface 100a, if viewed from the first display surface 100a, display light at a large viewing angle is a superposition of light that is used for image display of the display panel 100 and light that is emitted by the light source 410 and exits from the first display panel 100a. Therefore, the image displayed on the first display surface 100a by the display panel 100 cannot be viewed at a large viewing angle, which plays a privacy effect.

In addition, the second display surface 100b of the display device 1 may perform image display or not perform image display, that is, the second display surface 100b has two modes.

Further, when the first display surface 100a displays and the second display surface 100b also displays, the first display surface 100a and the second display surface 100b may display different contents.

Although embodiments of the present disclosure have been illustrated and described above, it can be understood that the above embodiments are exemplary and cannot be understood as limitations to the present disclosure. Those of ordinary skill in the art can change, amend, replace, and modify the above embodiments within the scope of the present disclosure, and these modifications and improvements are also regarded as the protection scope of the present disclosure.

What is claimed is:

1. A display device, comprising a display panel, a first transparent substrate, a second transparent substrate, a first dimming layer, a light source layer, a second dimming layer, a third transparent substrate, and a fourth transparent substrate that are sequentially stacked, the second transparent substrate has a greater refractive index than the first transparent substrate, the fourth transparent substrate has a less refractive index than the third transparent substrate, the first dimming layer comprises a plurality of first dimming units, the light source layer comprises a plurality of light sources, the second dimming layer comprises a plurality of second dimming units, each of the plurality of first dimming units and each of the plurality of second dimming units both have a first state of being a planar lens and a second state of being a concave lens; and the first dimming layer, the first transparent substrate, and the second transparent substrate cooperate with one another, and the second dimming layer, the third transparent substrate, and the fourth transparent substrate cooperate with one another, to make the display device have different display states.

2. The display device of claim 1, wherein the display panel has a first display surface away from the first transparent substrate, and the fourth transparent substrate has a second display surface away from the third transparent substrate; and
when the plurality of first dimming units each are in the first state and the plurality of second dimming units each are in the first state, the display device is in a first display mode, wherein the first display mode is a state in which the first display surface of the display device performs shared display and the second display surface of the display device does not display.

3. The display device of claim 1, wherein the display panel has a first display surface away from the first transparent substrate, and the fourth transparent substrate has a second display surface away from the third transparent substrate; and
when the plurality of first dimming units each are in the second state and the plurality of second dimming units each are in the first state, the display device is in a second display mode, wherein the second display mode is a state in which the first display surface of the display device performs privacy display and the second display surface of the display device does not display.

4. The display device of claim 1, wherein the display panel has a first display surface away from the first transparent substrate, and the fourth transparent substrate has a second display surface away from the third transparent substrate; and
when the plurality of first dimming units each are in the second state and the plurality of second dimming units each are in the second state, the display device is in a third display mode, wherein the third display mode is a state in which the first display surface of the display device performs privacy display and the second display surface of the display device displays.

5. The display device of claim 3, wherein the display panel comprises a light-emitting layer and a pixel definition layer, the light-emitting layer comprises a plurality of light-emitting units arranged at intervals, the pixel definition layer comprises a plurality of pixel definition portions arranged at intervals, each of the plurality of pixel definition portions comprises a pixel definition sub-portion and a light-shielding sub-portion, the pixel definition sub-portion has a bearing surface that is away from the first transparent substrate and a peripheral side surface that is connected to the bearing surface in a bent manner, the peripheral side surface comprises a first peripheral side sub-surface and a second peripheral side sub-surface, a side surface of each of the plurality of light-emitting units abuts against the first peripheral side sub-surface and avoids the second peripheral side sub-surface, the second peripheral side sub-surface is closer to the bearing surface than the first peripheral side sub-surface, and the bearing surface is used to bear the light-shielding sub-portion; and when the first display surface of the display device performs the privacy display, light emitted by the plurality of light sources passes through the second peripheral side sub-surface and exits through the first display surface.

6. The display device of claim 4, wherein the display panel comprises a light-emitting layer and a pixel definition layer, the light-emitting layer comprises a plurality of light-emitting units arranged at intervals, the pixel definition layer comprises a plurality of pixel definition portions arranged at intervals, each of the plurality of pixel definition portions comprises a pixel definition sub-portion and a light-shielding sub-portion, the pixel definition sub-portion has a bearing surface that is away from the first transparent substrate and a peripheral side surface that is connected to the bearing surface in a bent manner, the peripheral side surface comprises a first peripheral side sub-surface and a second peripheral side sub-surface, a side surface of each of the plurality of light-emitting units abuts against the first peripheral side sub-surface and avoids the second peripheral side sub-surface, the second peripheral side sub-surface is closer to the bearing surface than the first peripheral side sub-surface, and the bearing surface is used to bear the light-shielding sub-portion; and when the first display surface of the display device performs the privacy display, light emitted by the plurality of light sources passes through the second peripheral side sub-surface and exits through the first display surface.

7. The display device of claim 5, wherein the display panel further comprises an encapsulation layer, and the encapsulation layer is configured to encapsulate the light-emitting layer and the pixel definition layer.

8. The display device of claim 1, wherein the display panel has a first display surface away from the first transparent substrate, and the fourth transparent substrate has a second display surface away from the third transparent substrate;
the display device further has a fourth display mode, wherein the fourth display mode is a state in which the first display surface of the display device does not display and the second display surface of the display device displays; and
when the display device is in the fourth display mode, the plurality of first dimming units each are in the first state, and the plurality of second dimming units each are in the second state.

9. The display device of claim 1, wherein the display panel has a first display surface away from the first transparent substrate, and the fourth transparent substrate has a second display surface away from the third transparent substrate; and
when the plurality of first dimming units each are in the first state and the plurality of second dimming units each are in the second state, the display device is in a fifth display mode, wherein the fifth display mode is a state in which the first display surface of the display device performs shared display and the second display surface displays.

10. The display device of claim 4, wherein the plurality of light sources comprise a first light source, a second light source, and a third light source, and the first light source, the second light source, and the third light source are different from one another in color;
when the second display surface displays, one frame time for image display on the second display surface of the display device comprises a first sub-frame time, a second sub-frame time, and a third sub-frame time; and
the first light source is configured for display in the first sub-frame time; the second light source is configured for display in the second sub-frame time; and the third light source is configured for display in the third sub-frame time.

11. The display device of claim 8, wherein the plurality of light sources comprise a first light source, a second light source, and a third light source, and the first light source, the second light source, and the third light source are different from one another in color;
when the second display surface displays, one frame time for image display on the second display surface of the display device comprises a first sub-frame time, a second sub-frame time, and a third sub-frame time; and
the first light source is configured for display in the first sub-frame time; the second light source is configured for display in the second sub-frame time; and the third light source is configured for display in the third sub-frame time.

12. The display device of claim 9, wherein the plurality of light sources comprise a first light source, a second light source, and a third light source, and the first light source, the second light source, and the third light source are different from one another in color;
when the second display surface displays, one frame time for image display on the second display surface of the display device comprises a first sub-frame time, a second sub-frame time, and a third sub-frame time; and
the first light source is configured for display in the first sub-frame time; the second light source is configured for display in the second sub-frame time; and the third light source is configured for display in the third sub-frame time.

13. The display device of claim 5, wherein the plurality of first dimming units are aligned with the plurality of pixel definition portions in a one-to-one correspondence, and the plurality of first dimming units are aligned with the plurality of second dimming units in a one-to-one correspondence.

14. The display device of claim 5, wherein the plurality of first dimming units are aligned with the plurality of pixel definition portions in a one-to-one correspondence, and the plurality of second dimming units are aligned with the plurality of light-emitting units in a one-to-one correspondence; the display device further comprises a first light-shielding layer and a light-reflecting layer; and the first light-shielding layer comprises a plurality of first light-shielding portions arranged at intervals, the light-reflecting layer comprises a plurality of light-reflecting portions arranged at intervals, the plurality of first light-shielding portions are disposed on a surface of the third transparent substrate facing the second transparent substrate, and each of the plurality of light-reflecting portions is disposed on a surface of a corresponding first light-shielding portion facing the second transparent substrate.

15. The display device of claim 14, wherein the plurality of first light-shielding portions and the plurality of second dimming units are alternately arranged at intervals, and each of the plurality of light-reflecting portions avoids each of the plurality of second dimming units.

16. The display device of claim 15, wherein the display device further comprises a second light-shielding layer, and the second light-shielding layer comprises a plurality of second light-shielding portions arranged at intervals;
the light-emitting unit comprises a cathode sub-layer, a light-emitting sub-layer, and an anode sub-layer sequentially stacked, and the anode sub-layer is closer to the first transparent substrate than the cathode sub-layer; and
each of the plurality of second light-shielding portions is disposed at one side of a corresponding anode sub-layer close to the first transparent substrate.

17. The display device of claim 16, wherein each of the plurality of second light-shielding portions avoids each of the plurality of pixel definition portions.

18. The display device of claim 1, further comprising a first light-absorbing layer and a second light-absorbing layer, wherein
the first light-absorbing layer comprises a first light-absorbing portion and a second light-absorbing portion that are connected in a bent manner, the first light-absorbing portion is disposed on a surface of the second transparent substrate away from the first transparent substrate, the first light-absorbing portion is disposed at an edge of the second transparent substrate, and the second light-absorbing portion is disposed on a side surface of the first transparent substrate and a side surface of the second transparent substrate; and
the second light-absorbing layer comprises a third light-absorbing portion and a fourth light-absorbing portion that connected in a bent manner, the third light-absorbing portion is disposed on a surface of the third transparent substrate away from the fourth transparent substrate, the third light-absorbing portion is disposed at an edge of the third transparent substrate, and the fourth light-absorbing portion is disposed on a side surface of the third transparent substrate and a side surface of the fourth transparent substrate.

19. The display device of claim 18, wherein the second light-absorbing portion is configured to absorb light incident onto the side surface of the first transparent substrate and the side surface of the second transparent substrate; and
the fourth light-absorbing portion is configured to absorb light incident onto the side surface of the third transparent substrate and the side surface of the fourth transparent substrate.

20. The display device of claim 1, wherein an angle of light emitted by the plurality of light sources relative to the first transparent substrate is larger than a reflection angle at which total reflection occurs on the first transparent substrate, and an angle of light emitted by the plurality of light sources relative to the fourth transparent substrate is larger than a reflection angle at which total reflection occurs on the fourth transparent substrate.
